(19) United States
(12) Patent Application Publication
(10) Pub. No.: US 2009/0011942 A1
(43) Pub. Date: Jan. 8, 2009

(54) Method of Manufacturing MgB2 Superconducting Wire

(76) Inventors: YOON SANG LEE, Geumjeong-gu (KR); WOO HYUN CHUNG, Changwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/952,215

(22) Filed: Dec. 7, 2007

(30) Foreign Application Priority Data
Jul. 6, 2007 (KR) 10-2007-0068129

(51) Int. Cl. H01L 39/24

(52) U.S. Cl. 505/433; 29/599

(57) ABSTRACT

A method of manufacturing a superconducting wire is provided. A MgB₂ superconducting wire capable of obtaining a stabilizer through an inexpensive process can have high critical current density and magnetic field characteristics without separate plastic. A seamed portion of the wire can be welded to make it possible to plate the wire with conductive materials and inhibit a decrease in quality of superconducting powder. It is possible to obtain a stabilizer without inserting the superconducting powder into a tube.

### CROSS-REFERENCE TO RELATED APPLICATION

The present application claims the benefit under 35 U.S.C. §119 of Korean Patent Application No. 10-2007-0068129, filed Jul. 6, 2007, which is hereby incorporated by reference in its entirety.

### BACKGROUND OF THE INVENTION

1. Field of the Invention

The present invention relates to a method of manufacturing a superconducting wire, and more particularly, a method of manufacturing a MgB₂ superconducting wire.

2. Background of the Related Art

Generally, superconductivity is a phenomenon where a large amount of current can be supplied with minimal to no energy loss or electric resistance that can generate heat. Using the superconductivity phenomenon, it is possible to fabricate small-volume machines employing a high level of power with little to no energy loss. Superconductivity is leading the way with revolutionary changes in many fields, such as electricity/electronics, mechanics, atomic energy, medicine, and shipbuilding.

A superconducting wire can be classified into metal-based low temperature superconducting materials and oxide-based high temperature superconducting materials, depending on critical temperatures and the kind of material.

Metal-based low temperature superconducting wires can be further classified into alloy-based low temperature superconducting wires and compound-based low temperature superconducting wires. One example of a material used for an alloy-based low temperature superconducting wire is a niobium-titanium (Nb—Ti) superconducting material, which has already been commercialized and used as a superconducting coil for medical instruments such as magnetic resonance imaging (MRI) machines and nuclear magnetic resonance (NMR) machines. Niobium tin (Nb₃Sn) has a critical magnetic field higher than Nb—Ti and is a typical compound-based superconducting material. Nb₃Sn is used in superconducting magnets for a high magnetic field or a coil for nuclear fusion. However, since superconducting materials have critical temperatures less than 20K, in order to operate instruments formed of a metal-based superconducting wire, most superconducting materials should typically be cooled using liquid helium or an ultra-low refrigerator less than 10K.

Research on oxide-based superconducting materials, such as bismuth-based, yttrium-based, thallium-based superconducting materials, has been performed worldwide since these materials have a critical temperature higher than that of liquid nitrogen (77 K). Among oxide-based superconducting materials, bismuth-based Bi₂Sr₂Ca₂Cu₃Oₓ is the most widely used material for wire preparation. However, the bismuth-based superconducting wire has problems related to its crystalline structure, making it difficult to implement the wire's critical current density at more than 100,000 A/cm² in a magnetic field at a liquid nitrogen temperature of 77K. In addition, the critical current density to an external magnetic field decreases as the operating temperature increases.

Recently, it has been found that an intermetallic compound, such as magnesium diboride (MgB₂), exhibits superconducting characteristics at a temperature of about 39K (about −234° C.) as its electrical resistance disappears. In particular, there is little to no magnetic anisotropy, and it is possible for a powder of MgB₂ to display superconducting, such as particularly favorable characteristics under high temperature and high pressure conditions.

In order to put a superconducting device to practical use, it should exhibit good performance characteristics and be economically efficient. The most important factor for performance of the superconducting device is critical current density. This is because the critical current density varies greatly depending on the manufacturing method of the superconducting device, while the critical temperature and the critical magnetic field are inherent characteristics of the superconducting material and do not vary much with the manufacturing method.

A superconducting wire can include superconducting powder having superconducting characteristics, a covering material for accommodating the powder, a stabilizer for stably supplying electric power regardless of internal or external hazards, and a reinforcement material.

The covering material should be formed of a metal material or alloy which does not react with the superconducting powder. The covering material should also allow for easy treatment through rolling and drawing and should have high mechanical strength sufficient to endure a pressure applied due to the hardness of the superconducting powder when the covering material is rolled or drawn.

If a selected covering material has high electrical resistance, the superconducting state may be broken due to an increase in temperature caused by internal and external factors. In order to inhibit occurrence of this phenomenon, a metal material (a stabilizer) having low electrical resistance, high electrical conductivity, and high thermal conductivity can be applied onto the covering material, and the superconducting material can become unstable due to internal and external factors, making it difficult to apply a large amount of current. At this time, a current higher than the critical current passes through the superconducting material to transmit heat from around the superconducting material to the exterior to cool the superconducting material. This can help maintain the superconducting wire in its original state to supply current with little to no resistance.

The superconducting wire may be formed of a covering material and a stabilizer in a single wire (a single core wire) or in twisted plural wires (a multi-core wire) depending on the purpose and use of the wire. A reinforcement material surrounds the superconducting wire to protect the superconducting wire in use from external hazards and to process various diameters and shapes of the superconducting wire through drawing and rolling. The reinforcement material should be formed of a metal material or alloy that is stable at low temperatures (around 39 K) and has mechanical strength sufficient to endure a high pressure applied during drawing and rolling.

Methods of manufacturing a superconducting core wire using superconducting powder can be classified into a Powder-In-Tube (PIT) method and a Continuous Tube Forming and Filling (CTFF) method.

The PIT method includes filling raw material powder of a core wire in a metal tube (made of copper, silver, and an alloy thereof) used as a covering material (including a function of a stabilizer) to form a billet; plasticizing the billet through swaging, drawing, wire drawing, and rolling; and repeating heat treatment to attenuate work hardening generated during the plasticization to complete the superconducting core wire. The superconducting single core wire may be formed of the core wire completed through the above process, or the core wire may pass through a mold having a predetermined diameter and a hexagonal cross-section to form a hexagonal wire. The hexagonal wires are then integrated in a tube having a larger diameter than the hexagonal wire to form a multi-core wire.

In the case of a PIT method, a plurality of processes such as swaging, drawing, wire drawing, rolling, and heat treatment are repeated, thereby making it difficult to evenly control the processes. In particular, when the covering material is formed of copper, silver, and an alloy thereof having good electrical conductivity, MgB₂ superconducting powder cannot be uniformly pressurized due to high flexibility of the metals and high hardness of the MgB₂ superconducting powder, thereby producing a core wire having non-uniform critical current density. In addition, the high cost of the silver and the alloy decreases economical efficiency.

One method proposed to attempt to solve such problems is to use a metal having a yield strength of at least 300 MPa as a covering material and to electroplate a metal with low electrical resistance and high thermal conductivity to function as a stabilizer. However, since the basic manufacturing method is similar to the conventional method requiring a large number of processes, such as plasticization and heat treatment, and limiting the length of the tube, it is difficult to increase productivity and elongate a wire sufficiently to adapt the wire to various fields.

The Continuous Tube Forming and Filling (CTFF) method includes supplying a strip of covering material formed of iron, niobium, and an alloy thereof to form a certain shape for containing superconducting raw material powder; filling the superconducting raw material powder, such as MgB₂, in the formed strip of covering material; and forming, rolling, drawing, and heat treating the formed strip to manufacture a superconducting core wire. Next, a stabilizer is formed, and the superconducting core wire is inserted into the stabilizer as a single core wire or a twisted multi-core wire to be formed as a tube. Then, the superconducting core wire surrounded by the stabilizer is inserted into a reinforcement material and tube-formed to manufacture a superconducting single core wire or multi-core wire.

In order to manufacture a superconducting wire using the superconducting core wire manufactured by the CTFF method, a stabilizer should be used to obtain superconducting properties at a temperature and current that are higher than critical values. In addition, in order to achieve the properties, the superconducting core wire should be separately inserted into a tube formed of a stabilizer. However, when the tube is used, a continuous process is difficult to perform, thereby causing inefficiency. Also, when the tube forming is used, equipment and processes similar to manufacturing the conventional superconducting core wire are separately required, meaning that additional plasticization and heat treatment are required, thereby decreasing critical current characteristics and manufacturing efficiency, and increasing manufacturing costs.

Thus, there exists a need in the art for an improved method of manufacturing a superconducting wire.

### BRIEF SUMMARY

The present invention is directed to a method of manufacturing a magnesium diboride (MgB₂) superconducting wire capable of obtaining a stabilizer through a continuous and inexpensive process, without a separate plasticization process, thereby securing high critical current and magnetic field characteristics of an elongated MgB₂ superconducting core wire.

The present invention is also directed to a method of manufacturing a MgB₂ superconducting wire capable of minimizing plasticization and heat treatment for uniformizing critical current density during manufacture of single core and multi-core MgB₂ superconducting wires. In particular, a high density superconducting core wire during manufacture of the multi-core wire can be continuously and inexpensively manufactured.

In an embodiment of the present invention, a method of manufacturing a MgB₂ superconducting core wire can include: supplying a covering material formed as a metal strip; forming the covering material into a U-shaped tube to contain MgB₂ superconducting powder; filling the MgB₂ superconducting powder into the U-shaped covering material; forming the filled covering material into a tube shape; welding a seamed portion of the formed tube; rolling or drawing the welded tube; sintering the superconducting powder in the rolled or drawn tube or heat treating the tube to alleviate work hardening; and cleaning a work surface of the wire and then plating the wire with a conductive material to obtain a stabilizer.

In another embodiment of the present invention, a method of manufacturing superconducting single-core and multi-core wires can include: supplying a reinforcement material formed as a metal strip; forming the reinforcement material into a U-shaped tube to insert a MgB₂ superconducting wire; inserting a single MgB₂ superconducting core wire or plural MgB₂ superconducting core wires into the U-shaped reinforcement material; forming the reinforcement material, into which the MgB₂ superconducting single or multi-core wire is inserted, into a tube shape; welding a seamed portion of the formed tube; rolling or drawing the welded tube; and heat treating the tube.

### BRIEF DESCRIPTION OF THE DRAWINGS

FIG. 1 is a cross-sectional view showing processes of manufacturing a MgB₂ superconducting core wire according to an embodiment of the present invention.

FIG. 2 is a cross-sectional view showing processes of manufacturing a MgB₂ superconducting core which has the form of a single-core or multi-core wire according to an embodiment of the present invention.

### DETAILED DESCRIPTION OF THE INVENTION

Exemplary embodiments of the present invention will now be described in detail with reference to the accompanying drawings, throughout which like reference numerals refer to like elements.

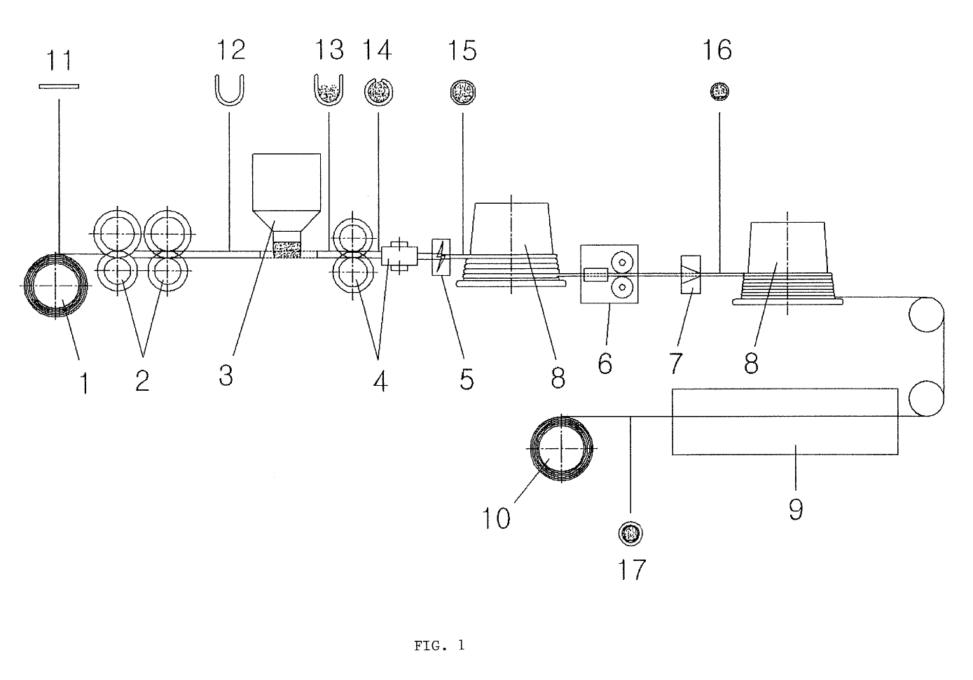

FIG. 1 is a cross-sectional view showing processes of manufacturing a MgB₂ superconducting core wire according to an embodiment of the present invention.

Referring to FIG. 1, a metal strip used as a covering material 11 can be wound on a spool 1 to be continuously supplied. The covering material 11 can be a metal material with a yield strength of more than 200 MPa and strength and impact toughness sufficient to protect the superconducting material from its own weight and external forces. The covering material 11 can be, for example, iron (Fe), nickel (Ni), titanium (Ti), copper (Cu), or an alloy of any combination thereof. In addition, the spools can be welded to each other in order to secure manufacturing continuity.

The prepared covering material 11 can be formed to have a U-shape 12 using a primary tube forming roller 2. A magnesium diboride (MgB₂) superconducting powder supply device 3 can distribute MgB₂ superconducting powder to fill the MgB₂ superconducting powder into the U-shaped tube 13. Then, the U-shaped tube can be formed into an O-shaped tube 14 using a secondary tube forming roller 4.

At this time, a seamed portion having a fine gap can be formed at the O-shaped tube. The seamed portion can be welded by a welding machine 5 using an electrical resistance heat source, a high frequency induction heat source, various flames, an arc heat source, a high density energy heat source (for example, plasma, laser beam, or electron beam), or other heat source, to seal the formed tube 15. Through the welding process of the seamed portion, it is possible to inhibit changes in quality of the MgB₂ superconducting powder and to effectively plate a stabilizer formed of a conductive material.

Next, the sealed tube can be cold-rolled using continuously arranged Cassette Roller Dies (CRD) 6, or drawn using a drawing die 7 to reduce a diameter of the tube. The drawing die can be, for example, a polycrystalline diamond die or a tungsten die. Through the series of processes, the MgB₂ superconducting powder can receive a uniform or nearly uniform pressure all over the wire to make the entire structure uniform (or nearly uniform) and dense, and to smooth the current flow.

Then, in order to make the structure of the MgB₂ superconducting powder denser and alleviate work hardening of the covering material, the tube can be heat treated at a temperature of about 800° C. to about 900° C. for about 1 hour to about 3 hours in an inert gas atmosphere, such as an argon atmosphere.

As described above, the MgB₂ superconducting powder can be filled in the covering material tube and then the tube can be drawn. Next, the drawn tube can be plated with a stabilizer to complete the MgB₂ superconducting wire.

In more detail, the stabilizer in the plating process can function as a safety device to radiate heat generated during conduction of high current in the superconducting wire manufacturing process and to discharge excessive current to the exterior. In the conventional art, a stabilizer metal plate formed of copper or aluminum is often separately supplied and formed into a U-shaped tube. The superconducting material is inserted into the tube, and the tube is formed to have an O-shape. At the same time, a reinforcement material is supplied to a final wire manufacturing process to improve productivity. However, in the conventional art, the process of replacing the stabilizer metal plate with another metal plate is very complicated. In addition, since the tube-forming process is simultaneously performed with the final wire manufacturing process, process control is also very difficult.

In order to solve such problems of the conventional art, in the present invention, MgB₂ superconducting powder can be filled in a covering material tube, and the tube can be drawn. Then, the drawn tube can be plated with a stabilizer through an in-line process. Therefore, it is possible to simplify the processes by removing the need to have simultaneous processes without a separate stabilizer forming insertion process.

That is, the drawn tube can pass through a degreasing, cleaning, and plating bath 9, in which conductive ions acting as a stabilizer are melted, to form a plated layer 17 on a surface of the tube, thereby completing the MgB₂ superconducting core wire. The conductive material can be any suitable material known in the art, for example, Cu, aluminum (Al), silver (Ag), or an alloy thereof.

In order to effectively plate a stabilizer, a process of welding a seamed portion after forming the covering material O-shaped tube is introduced. This can inhibit contamination and change in quality of superconducting powder, which may be generated when a plating solution is flowed through the seamed portion.

The MgB₂ superconducting core wire manufactured as described above can be wound on a spool to be continuously used in another superconducting wire manufacturing process.

Then, in order to lower the specific resistance of the stabilizer, the wire can be heat treated at a temperature lower than the decomposition temperature of MgB₂.

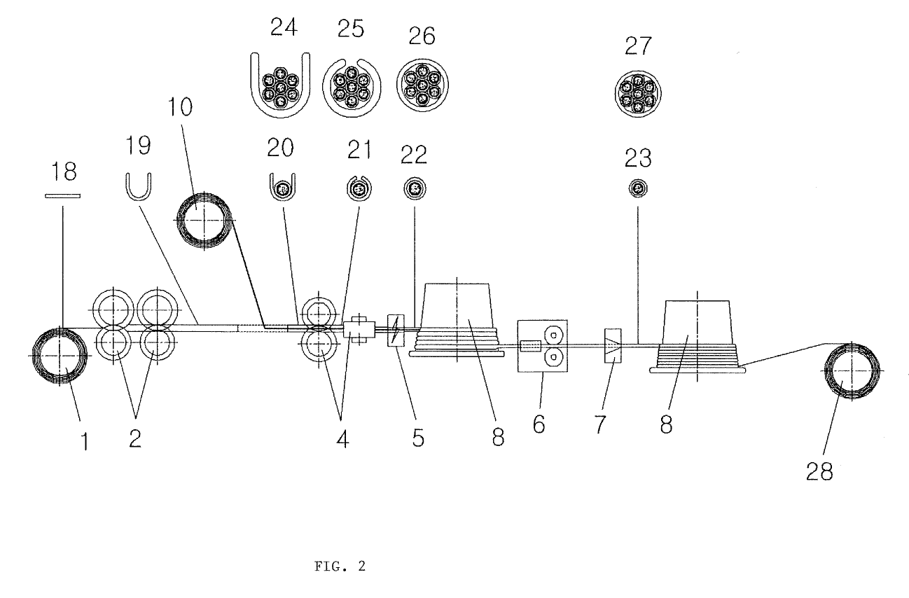

FIG. 2 is a cross-sectional view showing processes of manufacturing a MgB₂ superconducting core which has the form of a single-core or multi-core wire according to an embodiment of the present invention.

Referring to FIG. 2, a metal strip used as a reinforcement material 18 can be wound on a spool 1 to be continuously supplied. The reinforcement material 18 can be, for example, Fe, Ni, Ti, Cu, or an alloy thereof. In addition, the respective spools can be welded to each other for the purpose of manufacturing continuity.

The reinforcement material 18 can be formed in a U-shape using a primary tube forming roller 2. The MgB₂ superconducting core wire 10 wound on the spool can be inserted into the tube as a single core 20 or a twisted multi-core 24, and then the tube can be formed as an O-shaped tube 21 (for single core) or 25 (for twisted multi-core) using a secondary tube forming roller 4.

At this time, the formed O-shaped tube can also be welded by a welding machine 5 using the same heat source as the core wire to seal the formed tube 22 (for single core) or 26 (for twisted multi-core), thereby inhibiting intrusion of foreign substances into the superconducting wire from the exterior.

Then, the tube can be cold-rolled by a continuously arranged CRD 6 or drawn by a drawing die 7 to reduce the diameter of the tube. The drawing die can be, for example, a polycrystalline diamond die or a tungsten die. Through the series of processes, the MgB₂ superconducting powder, the covering material, a gap between the stabilizer plated layer and the reinforcement material, and a space between the respective single-core wires can be integrated to complete the resultant MgB₂ superconducting single-core wire 23 or multi-core wire 27 having uniform (or nearly uniform) properties and high critical current density.

Next, heat treatment can be performed to obtain a denser structure of the MgB₂ superconducting powder and alleviate work hardening of the covering material.

### EXAMPLE 1

Stainless steel 304L selected as a covering material was continuously supplied to form a U-shaped tube using a primary tube forming roller, and MgB₂ superconducting powder was filled in the tube. Then, an O-shaped tube was formed using a secondary tube forming roller, and a seamed portion of the tube was welded by gas tungsten arc welding (GTAW). Next, the tube was rolled using a CRD to reduce the diameter of the tube, and heat treatment was performed to alleviate work hardening.

At this time, due to work hardening characteristics of the stainless steel 304L, heat treatment was performed on the stainless steel 304L to inhibit inferior quality of the products.

Then, the tube passed through an electroplating bath, in which copper ions were melted, to form a copper plated layer on a surface of the tube, thereby obtaining a MgB₂ superconducting core wire wound on the spool.

Next, Monel 400 formed of a Ni—Cu alloy was selected as a reinforcement material to manufacture a single-core wire. The Monel 400 was continuously supplied to form a U-shaped tube. Then, the MgB₂ superconducting core wire was inserted into the U-shaped tube to form an O-shaped tube, and a seamed portion was welded by GTAW. Next, the tube was rolled and drawn using a CRD.

The drawn tube was heat treated at a temperature of 900° C. for 1 hour, 2 hours, and 3 hours in an inert gas atmosphere, for example, an argon gas atmosphere, to manufacture the MgB₂ superconducting single-core wire.

As a result of measuring critical current density (Jc) using a 4-terminal conduction method, the results shown in Table 1 were obtained.

TABLE 1
Filling rate, critical current, and critical current density
at different heat treatment conditions

| | Heat treatment | Filling rate | Ic (at 20K) | Jc (at 20K) |
|---|---|---|---|---|
| Example | conditions | [%] | [A] | [A/cm²] |
| 1 | 900° C./1 hour | 20 | 164 | 5.7 × 10⁴ |
| 2 | 900° C./2 hours | 20 | 219 | 8.3 × 10⁴ |
| 3 | 900° C./3 hours | 20 | 53 | 2.3 × 10⁴ |

Referring to Table 1, the MgB₂ superconducting single-core wire had a uniform filling rate of superconducting powder, and the critical current density was more than 50,000 A/cm² at 20K, in particular, 83,000 A/cm² in the case of the heat treatment for 2 hours.

As can be seen from the foregoing, a metal strip as a covering material can be continuously supplied to form a tube to thereby uniformly (or nearly uniformly) increase a filling rate of MgB₂ superconducting powder, thereby increasing critical current density. Also, using the covering material formed of high strength metal, a high load can be uniformly (or nearly uniformly) applied to the MgB₂ superconducting powder during plasticization to make the entire structure uniform (or nearly uniform) and dense, thereby increasing the critical current density.

In addition, different from the conventional art, the MgB₂ superconducting powder can be filled in a U-shaped tube to form an O-shaped tube, and a seamed portion of the O-shaped tube can be welded to enable the tube to be plated with a stabilizer. As a result, it is possible to obtain the stabilizer to rapidly radiate resistance heat generated from the superconducting wire caused by external factors or discharging excessive current, without a tube or a separate superconducting core wire-inserting process through a tube-forming process.

Furthermore, when the MgB₂ superconducting single-core or multi-core wire is manufactured, the number of processes can be reduced to continuously manufacture the superconducting wire having uniform (or nearly uniform) performance and elongated length at low costs. In particular, when the multi-core wire is manufactured, a high-density superconducting core wire can be continuously manufactured at low costs, thereby enabling more rapid commercialization of the MgB₂ superconducting wire.

While exemplary embodiments of the present invention have been shown and described, it will be appreciated by those skilled in the art that various changes may be made to these exemplary embodiments without departing from the spirit and scope of the invention as defined by the appended claims and their equivalents.

What is claimed is:

1. A method of manufacturing a magnesium diboride (MgB₂) superconducting core wire, comprising:
supplying a covering material formed as a metal strip;
forming the covering material into a U-shaped tube;
filling MgB₂ superconducting powder into the U-shaped covering material;
forming the covering material into an O-shaped tube;
welding a seamed portion of the O-shaped tube;
rolling or drawing the welded tube; and
plating a surface of the tube with a conductive material to obtain a stabilizer function.

2. The method according to claim 1, wherein the covering material formed as a metal strip is continuously supplied.

3. The method according to claim 1, further comprising sintering the superconducting powder in the rolled or drawn tube or heat treating the tube to attenuate work hardening after rolling or drawing the welded tube.

4. The method according to claim 1, wherein the covering material formed as a metal strip comprises iron (Fe), nickel (Ni), titanium (Ti), copper (Cu), or an alloy thereof.

5. The method according to claim 1, wherein the welded tube is rolled using a cassette roll die or is drawn using a drawing die.

6. The method according to claim 5, wherein the drawing die is a polycrystalline diamond die or a tungsten die.

7. The method according to claim 1, wherein the conductive material comprises copper (Cu), aluminum (Al), silver (Ag), or an alloy thereof.

8. The method according to claim 1, wherein plating the surface of the tube with the conductive material comprises passing the welded tube through a plating bath, and wherein the plating bath comprises the conductive material.

9. A method of manufacturing a MgB₂ superconducting wire, comprising:
supplying a reinforcement material formed as a metal strip;
forming the reinforcement material into a U-shaped tube;
inserting a MgB₂ superconducting wire into the U-shaped tube;
forming the reinforcement material, into which the MgB₂ superconducting single-core wire is inserted, into an O-shaped tube;
welding a seamed portion of the O-shaped tube; and
rolling or drawing the welded tube.

10. The method according to claim 9, wherein the MgB₂ superconducting wire is a MgB₂ superconducting twisted multi-core wire.

11. The method according to claim 9, wherein the MgB₂ superconducting wire is a MgB₂ superconducting single-core wire.

12. The method according to claim 11, wherein the MgB₂ superconducting single-core wire is manufactured by the method of claim 1.

13. The method according to claim 12, wherein the reinforcement material formed as a metal strip is continuously supplied.

14. The method according to claims 12, further comprising sintering the superconducting powder in the rolled or drawn tube or heat treating the tube to attenuate work hardening after rolling or drawing the welded tube.

15. The method according to claims 12, wherein the reinforcement material formed as a metal strip comprises Fe, Ni, Ti, Cu, or an alloy thereof.

16. The method according to claims 12, wherein the welded tube is rolled using a cassette roll die or is drawn using a drawing die.

17. The method according to claim 16, wherein the drawing die is a polycrystalline diamond die or a tungsten die.
